(19) United States
(12) Patent Application Publication
(10) Pub. No.: US 2021/0151597 A1
(43) Pub. Date: May 20, 2021

(54) SEMICONDUCTOR DEVICE

(71) Applicant: Sanken Electric Co., Ltd., Niiza-shi, Saitama (JP)

(72) Inventor: Yuji TASAKI, Niiza-shi (JP)

(73) Assignee: Sanken Electric Co., Ltd., Niiza-shi, Saitama (JP)

(21) Appl. No.: 17/056,867

(22) PCT Filed: May 22, 2018
(86) PCT No.: PCT/JP2018/019673

§ 371 Date: Nov. 19, 2020

(51) Int. Cl. H01L 29/78; H01L 29/06; H01L 29/10

(52) U.S. Cl. CPC H01L 29/7802; H01L 29/1095; H01L 29/0634

(57) ABSTRACT

A SJ power MOSFET having a super junction structure includes a P⁻ pillar layer buried in a drift layer as an N⁻ pillar layer and including a P pillar upper layer and a P pillar lower layer, wherein the P⁻ pillar layer is configured to fulfill the relationships: Db>Da and Ca>Cb, where Da is a defect density of the P pillar upper layer, Ca is an impurity concentration of the P pillar upper layer, Db is a defect density of the P pillar lower layer, and Cb is an impurity concentration of the P pillar lower layer, so as to achieve a higher switching speed and ensure higher breakdown stability.

### TECHNICAL FIELD

The present invention relates to a semiconductor device having a super junction (SJ) structure (a SJ power MOSFET).

### BACKGROUND ART

Super junction (SJ) power MOSFETs are known as a semiconductor element having a high breakdown voltage and a low on-resistance due to its SJ structure (refer to Patent Documents 1 and 2).

Another type of semiconductor device is disclosed that includes a lifetime control region formed in the entire region in the device including Schottky barrier diodes having the SJ structure so as to achieve a low resistance and a high breakdown voltage and improve a reverse-recovering property (refer to Patent Document 3).

The demand for the technique of forming such a lifetime control region (the lifetime control technique) has grown to improve the switching characteristics of a power semiconductor device such as a power MOSFET. The lifetime control technique refers to a technique of irradiating a power semiconductor device with several MeV or greater of an electron beam or a high-energy light-ion beam to form lattice defects (crystal defects) so as to improve the device characteristics.

### CITATION LIST

### Patent Literature

### [PTL 1] Japanese Unexamined Patent Application Publication No. 2007-19146

### [PTL 2] Japanese Unexamined Patent Application Publication No. 2008-258442

### [PTL 3] Japanese Unexamined Patent Application Publication No. 2008-258313

### SUMMARY OF INVENTION

### Technical Problem

Patent Documents 1 to 3 described above, which all relate to the semiconductor element (the semiconductor device) having the SJ structure capable of achieving a low resistance (a low on-resistance) and a high breakdown voltage to some extent, still need to achieve a higher switching speed and ensure higher breakdown stability.

The present invention provides a semiconductor device contributing to both achieving a higher switching speed and ensuring higher breakdown stability.

### Solution to Problem

An aspect of the present invention provides a semiconductor device includes: a first-conductivity-type substrate; a first-conductivity-type semiconductor region provided on a top surface of the first-conductivity-type substrate; a second-conductivity-type diffusion region selectively provided in a surface region of the first-conductivity-type semiconductor region; a first-conductivity-type diffusion region selectively provided in a surface region of the second-conductivity-type diffusion region; a second-conductivity-type pillar layer buried in the first-conductivity-type semiconductor region to be connected to at least part of a lower portion of the second-conductivity-type diffusion region; a control electrode provided via an insulating film on a top surface of the second-conductivity-type diffusion region, on a top surface of the first-conductivity-type semiconductor region adjacent to the second-conductivity-type diffusion region, and on at least part of a top surface of the first-conductivity-type diffusion region adjacent to the second-conductivity-type diffusion region; a first main electrode joined to a bottom surface of the first-conductivity-type substrate; and a second main electrode joined to the second-conductivity-type diffusion region and the first-conductivity-type diffusion region. The second-conductivity-type pillar layer includes a layer upper part and a layer lower part, and fulfills relationships: Db>Da and Ca>Cb, where Da is a defect density of the layer upper part, Ca is an impurity concentration of the layer upper part, Db is a defect density of the layer lower part, and Cb is an impurity concentration of the layer lower part.

### Advantageous Effects of Invention

The semiconductor device according to the present invention can accelerate the switching speed and control the breakdown voltage such that the pillar layer implementing the super junction structure has the defect density Db of the layer lower part which is higher than the defect density Da of the layer upper part, and the impurity concentration Cb of the layer lower part which is lower than the impurity concentration Ca of the layer upper part.

### BRIEF DESCRIPTION OF DRAWINGS

FIG. 1 is a schematic cross-sectional view illustrating a configuration of a SJ power MOSFET according to a first embodiment of the present invention.

FIG. 2 is a schematic cross-sectional view schematically illustrating the characteristics of the SJ power MOSFET shown in FIG. 1.

FIG. 3 is a schematic cross-sectional view for explaining a method of manufacturing a SJ power MOSFET while referring to the SJ power MOSFET illustrated in FIG. 1.

FIG. 4 is a schematic cross-sectional view illustrating a configuration of a SJ power MOSFET according to a second embodiment of the present invention.

FIG. 5 is a schematic cross-sectional view illustrating a configuration of a SJ power MOSFET according to a third embodiment of the present invention.

### DESCRIPTION OF EMBODIMENT

Some embodiments according to the present invention are described below with reference to the drawings. In the explanations of the drawings below, the same or similar components are denoted by the same or similar reference numerals. The embodiments described below illustrate a device and a method for embodying the technical ideas of the present invention, but the technical ideas of the present invention are not intended to be limited to the shapes, structures, or arrangements of the constituent elements as described herein. Various modifications can be made to the respective embodiments of the present invention within the scope of the appended claims.

The respective semiconductor devices having a super junction (SJ) structure according to the following embodiments are illustrated with a SJ power metal-oxide semiconductor field-effect transistor (MOSFET).

### First Embodiment

<Configuration>

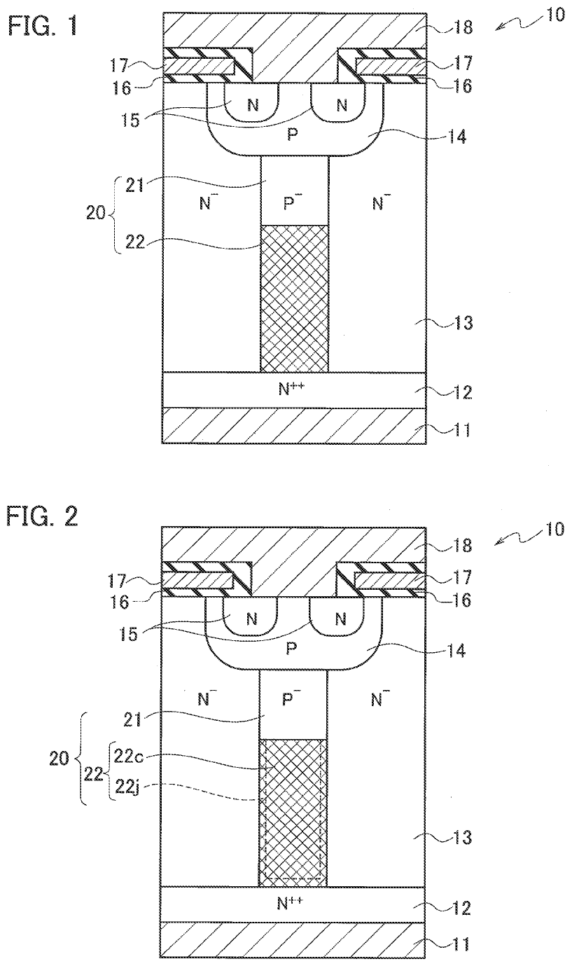

A SJ power MOSFET 10 according to a first embodiment of the present invention is a high-power semiconductor device having a SJ structure, for example, as illustrated in FIG. 1. The SJ power MOSFET 10 has a P-N junction implemented by a drift layer (a first-conductivity-type semiconductor region) 13 serving as an N⁻ pillar layer, and a P layer 20 having a pillar-like shape (referred to below as a P⁻ pillar layer) buried in the drift layer 13.

The P⁻ pillar layer 20 includes a P pillar upper layer 21 as a layer upper part and a P pillar lower layer 22 as a layer lower part. The P pillar lower layer 22 has lattice defects (crystal defects) formed by irradiation (light-ion irradiation) described below.

More particularly, the SJ power MOSFET 10 according to the first embodiment includes a drain (N⁺⁺ substrate) layer 12 of a first conductivity type, and the drift layer (the N⁻ pillar layer) 13 of the first conductivity type formed on the top surface of the drain layer 12, as illustrated in FIG. 1. The SJ power MOSFET 10 also includes the P⁻ pillar layer 20 buried in the drift layer 13 and including the P pillar upper layer 21 and the P pillar lower layer (the lattice defects) 22. The P⁻ pillar layer 20 has a depth such that the bottom surface of the P pillar lower layer 22 is brought into contact with the top surface of the drain layer 12, for example.

The SJ power MOSFET 10 further includes a diffusion region (a P base region) 14 of a second conductivity type provided in a surface region of the drift layer 13 and connected to the P pillar upper layer 21 of the P⁻ pillar layer 20, and a diffusion region (an N source region) 15 of the first conductivity type selectively buried in a surface region of the P base region 14.

The SJ power MOSFET 10 also includes a plurality of control electrodes (gate electrodes) 17 deposited on the top surface of the drift layer 13, a part of the top surface of the N source region 15, and the top surface of the P base region 14 via insulating films (gate insulating films) 16. The SJ power MOSFET 10 further includes a first main electrode (a drain electrode) 11 deposited on the bottom surface of the drain layer 12, and a second main electrode (a source electrode) 18 joined to the P base region 14 and the N source region 15.

FIG. 1 illustrates the SJ power MOSFET 10 with the structure including the single P⁻ pillar layer 20 for illustration purposes. The SJ power MOSFET 10 may include a plurality of P⁻ pillar layers 20.

As described in detail below, the crystal defects of the P pillar lower layer 22 can be formed by the irradiation (the light-ion irradiation) with a beam from the device surface side executed, for example, after the completion of the device structure (called the lifetime control technique).

<Characteristics>

In the SJ power MOSFET 10 according to the first embodiment, the P⁻ pillar layer 20 is configured to fulfill the following relationships:

Db>Da and Ca>Cb

where Da is a defect density of the P pillar upper layer 21, Ca is an impurity concentration of the P pillar upper layer 21, Db is a defect density of the P pillar lower layer 22, and Cb is an impurity concentration of the P pillar lower layer 22.

In particular, the P pillar upper layer 21 has the defect density Da in a range of about 3×10⁶ to 5×10⁷ cm-³, and the impurity concentration Ca in a range of about 3×10¹⁵ to 5×10¹⁸ cm-³.

The P pillar lower layer 22 has the defect density Db in a range of about 5×10⁶ to 5×10¹⁴ cm-³, and the impurity concentration Cb in a range of about 3×10⁴ to 5×10¹⁷ cm-³.

The SJ power MOSFET 10 according to the first embodiment thus includes the P⁻ pillar layer 20 to be formed such that the defect density Db of the P pillar lower layer 22 is higher than the defect density Da of the P pillar upper layer 21, and the impurity concentration Cb of the P pillar lower layer 22 is lower than the impurity concentration Ca of the P pillar upper layer 21.

As illustrated in FIG. 2, in the SJ power MOSFET 10 according to the first embodiment, the defect density Db of the P pillar lower layer 22 of the P⁻ pillar layer 20 is set such that a defect density Dbj of a circumferential part 22j adjacent to the P-N junction is lower than a defect density Dbc of a central part 22c (Dbc>Dbj). The impurity concentration Cb of the P pillar lower layer 22 is set such that an impurity concentration Cbj of the circumferential part 22j adjacent to the P-N junction is higher than an impurity concentration Cbc of the central part 22c (Cbc<Cbj).

<Manufacturing Method>

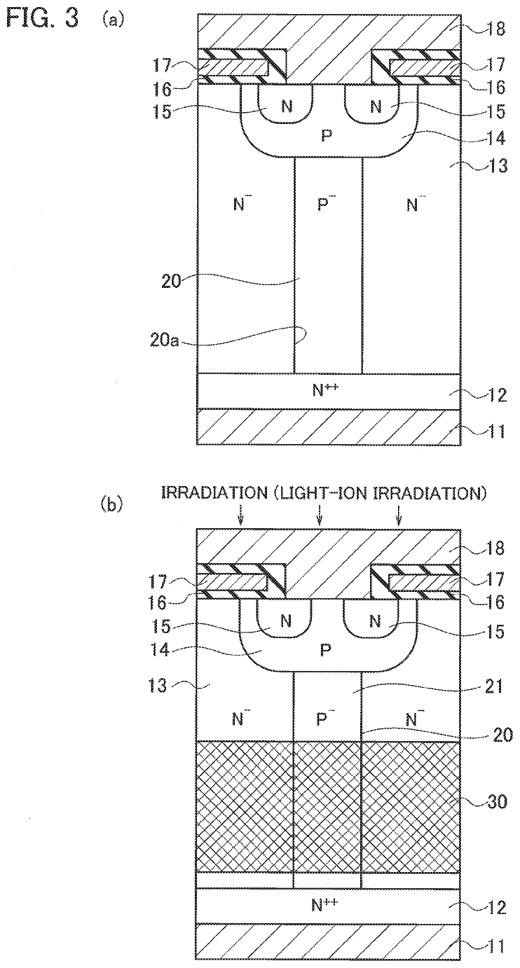

A method of manufacturing the SJ power MOSFET 10 is illustrated below with reference to FIG. 3(a) and FIG. 3(b). FIG. 3(a) is a schematic cross-sectional view of the SJ power MOSFET 10 during the manufacturing process for the device structure, and FIG. 3(b) is a schematic cross-sectional view during the forming process for the crystal defects.

The method of manufacturing the SJ power MOSFET 10 according to the first embodiment first epitaxially grows the N⁻-type drift layer 13 on the N-type drain layer 12, as illustrated in FIG. 3(a). A mask such as a SiO₂ film or a Si₃N₄ film (not illustrated) is coated on the surface of the drift layer 13 by thermal oxidation, and the mask is delineated by photolithography to conform to the P⁻ pillar layer 20 to be formed. A trench 20a having a depth reaching the drain layer 12 is then formed in the drift layer 13 by wet etching or dry etching such as reactive ion etching (RIE). The impurity concentration of the drift layer 13 at this point is about 1.5×10¹⁵ cm⁻³ and the thickness is about 50 μm, and the depth of the trench 20a is about 50 μm.

Next, the mask is removed by wet etching, for example, and an epitaxially-grown layer of P-type having a higher impurity concentration than the drift layer 13 is deposited in the trench 20a so as to form the P⁻ pillar layer 20. The surface of the P⁻ pillar layer 20 is then flattened by a chemical mechanical polishing (CMP) method, for example. The impurity concentration of the P⁻ pillar layer 20 at this point is about 3×10¹⁵ to 5×10¹⁸ cm-³ which is the impurity concentration Ca of the P pillar upper layer 21, and the defect density of the P⁻ pillar layer 20 is about 3×10⁶ to 5×10⁷ cm-³ which is the defect density Da of the P pillar upper layer 21.

Next, a SiO₂ film is deposited on the surfaces of the P⁻ pillar layer 20 and the drift layer 13 by thermal oxidation, and is delineated by photolithography so as to form a mask (not illustrated). The mask is then subjected to predetermined ion implantation and thermal diffusion so as to form the P base region 14 in the surface region of the P-pillar layer 20 and the drift layer 13. The N source region 15 is also formed in the surface region of the P base region 14 through the similar process.

Next, the gate electrodes 17 covered with the gate insulating films 16 are formed to cover a part of the top surfaces of the N source region 15, the top surfaces of the P base region 14, and the top surface of the drift layer 13. The source electrode 18 is deposited on the device top surface to be joined to the N source region 15 and the P base region 14, and the drain electrode 11 is deposited on the device bottom surface to be joined to the drain layer 12, so as to complete the device structure of the SJ power MOSFET 10 as illustrated in FIG. 3(a).

After the completion of the device structure, the SJ power MOSFET 10 is subjected to the irradiation with a beam from the top surface of the source electrode 18 under predetermined conditions, as illustrated in FIG. 3(b). A defect layer 30 having preferable properties with a thickness of about 25 μm is thus formed at the layer lower part of the drift layer 13 including the layer lower part of the P⁻ pillar layer 20. The predetermined conditions for forming the defect layer 30 with the preferable properties are set such that protons H⁺ are used as accelerated ions, the dose is in a range of about 10¹⁰/cm² to 10¹²/cm², and acceleration energy is about 4.5 MeV.

A chip is then subjected to local annealing with a semiconductor laser with a wavelength of 445 nm and a laser output of 8.0 W so as to remove the defect layer 30 formed at the layer lower part of the drift layer 13. This process forms the crystal defects with the defect density Db of about 5×10⁶ to 5×10¹⁴ cm-³ and the impurity concentration Cb of about 3×10¹⁴ to 5×10¹⁷ cm-³ in the P pillar lower layer 22 of the P⁻ pillar layer 20.

The method described above thus forms the P pillar lower layer 22 having the stable crystal defects only at the layer lower part of the P⁻ pillar layer 20, so as to provide the SJ power MOSFET 10 having the structure as illustrated in FIG. 1.

As described above, the SJ power MOSFET 10 has the crystal defects of the P pillar lower layer 22 in the P⁻ pillar layer 20 of the SJ structure. The P pillar lower layer 22 of the P⁻ pillar layer 20 includes the crystal defects having the lower impurity concentration and the higher crystal defect density than the P pillar upper layer 21. This provides a difference in the impurity concentration and the density of the crystal defects between the upper and lower parts of the P⁻ pillar layer 20. The difference can accelerate the switching speed of the SJ power MOSFET 10 and lead the P pillar lower layer 22 to have a lower impurity concentration, so as to facilitate the breakdown control. The SJ power MOSFET 10 according to the first embodiment thus contributes to achieving a higher switching speed and ensuring higher breakdown stability than a case of simply varying the impurity concentration and the total impurity amount between the upper and lower parts of the SJ structure.

### Second Embodiment

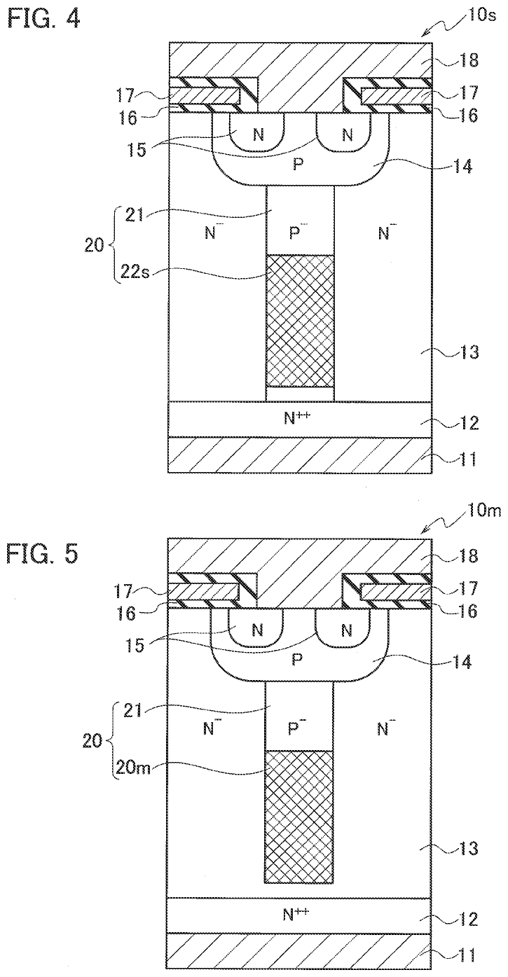

FIG. 4 illustrates a configuration of a SJ power MOSFET 10s according to a second embodiment of the present invention.

The SJ power MOSFET 10s according to the second embodiment has the configuration including the P⁻ pillar layer 20 having a depth such that the bottom surface is brought into contact with the top surface of the drain layer 12, and provided with a P pillar lower layer 22s in the middle part of the P⁻ pillar layer 20, as illustrated in FIG. 4. Namely, the P pillar lower layer 22s of the P⁻ pillar layer 20 in the SJ power MOSFET 10s is provided at the depth such that the bottom surface of the crystal defects does not reach the top surface of the drain layer 12.

The other configurations are the same as those in the SJ power MOSFET 10 according to the first embodiment, and specific explanations are not repeated below.

The SJ power MOSFET 10s according to the second embodiment can also achieve the same effects as the case of the SJ power MOSFET 10 according to the first embodiment described above.

### Third Embodiment

FIG. 5 illustrates a configuration of a SJ power MOSFET 10m according to a third embodiment of the present invention.

The SJ power MOSFET 10m according to the third embodiment has the configuration including the P⁻ pillar layer 20 having a depth such that the bottom surface does not reach the top surface of the drain layer 12, and provided with a P pillar lower layer 22m at the layer lower part of the P⁻ pillar layer 20, as illustrated in FIG. 5.

The other configurations are the same as those in the SJ power MOSFET 10 according to the first embodiment, and specific explanations are not repeated below.

The SJ power MOSEET 10m according to the third embodiment can also achieve the same effects as the case of the SJ power MOSFET 10 according to the first embodiment described above.

The SJ power MOSFETs 10, 10s, and 10m according to the respective embodiments illustrated above are not limited to the power MOSFETs. For example, the SJ power MOSFETs 10, 10s, and 10m can be used as various types of semiconductor devices having the SJ structure other than the high-power semiconductor device.

While the respective embodiments are illustrated above with the case in which the first conductivity type is the N-type and the second conductivity type is the P-type, such as the P⁻ pillar layer 20, the respective embodiments may also be applied to a case in which the first conductivity type is the P-type and the second conductivity type is the N-type so as to have a SJ structure including an N⁻ pillar layer.

### Other Embodiments

While the present invention has been described above by reference to the respective embodiments, it should be understood that the present invention is not intended to be limited to the descriptions and the drawings composing part of this disclosure. Various alternative embodiments, examples, and technical applications will be apparent to those skilled in the art according to this disclosure.

It should also be understood that the present invention includes various embodiments not disclosed herein. Therefore, the technical scope of the present invention is defined only by the subject matter according to the claims reasonably derived from the foregoing descriptions.

### INDUSTRIAL APPLICABILITY

The semiconductor device according to the present invention can be used for various types of semiconductor devices having a SJ structure.

1. A semiconductor device comprising:
a first-conductivity-type substrate;
a first-conductivity-type semiconductor region provided on a top surface of the first-conductivity-type substrate;
a second-conductivity-type diffusion region selectively provided in a surface region of the first-conductivity-type semiconductor region;
a first-conductivity-type diffusion region selectively provided in a surface region of the second-conductivity-type diffusion region;
a second-conductivity-type pillar layer buried in the first-conductivity-type semiconductor region to be connected to at least part of a lower portion of the second-conductivity-type diffusion region;
a control electrode provided via an insulating film on a top surface of the second-conductivity-type diffusion region, on a top surface of the first-conductivity-type semiconductor region adjacent to the second-conductivity-type diffusion region, and on at least part of a top surface of the first-conductivity-type diffusion region adjacent to the second-conductivity-type diffusion region;
a first main electrode joined to a bottom surface of the first-conductivity-type substrate; and
a second main electrode joined to the second-conductivity-type diffusion region and the first-conductivity-type diffusion region,
wherein the second-conductivity-type pillar layer includes a layer upper part and a layer lower part, and fulfills relationships:
Db>Da and Ca>Cb
where Da is a defect density of the layer upper part, Ca is an impurity concentration of the layer upper part, Db is a defect density of the layer lower part, and Cb is an impurity concentration of the layer lower part.

2. The semiconductor device according to claim 1, wherein the second-conductivity-type pillar layer has a depth reaching the top surface of the first-conductivity-type substrate.

3. The semiconductor device according to claim 1, wherein:
the defect density Da of the layer upper part is in a range of 3×10⁶ to 5×10⁷ cm-³;
the defect density Db of the layer lower part is in a range of 5×10⁶ to 5×10¹⁴ cm-³;
the impurity concentration Ca of the layer upper part is in a range of 3×10¹⁵ to 5×10¹⁸ cm-³; and
the impurity concentration Cb of the layer lower part is in a range of 3×10¹⁴ to 5×10¹⁷ cm-³.

4. The semiconductor device according to claim 1 wherein:
the defect density Db of the layer lower part is set such that a defect density Dbj of a circumferential part of the layer lower part excluding a central part of the layer lower part is lower than a defect density Dbc of the central part; and
the impurity concentration Cb of the layer lower part is set such that an impurity concentration Cbj of the circumferential part of the layer lower part excluding the central part is higher than an impurity concentration Cbc of the central part.
